(19) United States
(12) Patent Application Publication
(10) Pub. No.: US 2021/0220861 A1
(43) Pub. Date: Jul. 22, 2021

(54) DRY TYPE ULTRASONIC CLEANER HAVING A MULTI-SUCTION PORT

(71) Applicant: PSM Inc., Gyeonggi-do (KR)

(72) Inventor: Keun-Ho Lee, Seoul (KR)

(73) Assignee: PSM Inc., Gyeonggi-do (KR)

(21) Appl. No.: 16/790,447

(22) Filed: Feb. 13, 2020

(30) Foreign Application Priority Data
Jan. 20, 2020 (KR) 10-2020-0007121

(51) Int. Cl. B05B 17/06; B08B 11/04; B08B 5/02

(52) U.S. Cl. CPC B05B 17/06; B08B 5/02; B08B 11/04

(57) ABSTRACT

Provided is a dry type ultrasonic cleaner having a multi-suction port that can quickly, uniformly, and reliably remove particles on a product through the multi-suction port without scattering, and in particular, can remove a wide range of particles having a size of several micrometers to several millimeters, thereby securing product competitiveness.

### CROSS REFERENCE TO PRIOR APPLICATIONS

The present application claims priority under 35 U.S.C. § 119 to Korean Patent Application No. 10-2020-0007121 (filed on Jan. 20, 2020).

### BACKGROUND

### Field of the Invention

The present invention relates to a dry type ultrasonic cleaner having a multi-suction port, and more particularly, to a dry type ultrasonic cleaner having a multi-suction port that can generate ultrasonic waves through a uniform pneumatic to quickly, uniformly, and reliably remove particles on a product through the multi-suction port without scattering, and in particular, can remove a wide range of particles having a size of several micrometers to several millimeters, thereby securing product competitiveness.

### Related Art

Particulates present in semiconductors, display substrates, or glass substrates can cause operational errors or product defects. Therefore, particulates or foreign matters should be removed in advance during the manufacture of the product. To this end, a cleaner may be used. As the cleaner, there may be a wet type cleaner using a solution and a brush to remove foreign matters and a dry type cleaner using air. In this case, the wet type cleaner or the dry type cleaner may be used depending on a type of substrates. On the other hand, different types of cleaners can be applied to the particulates to be removed, depending on a size or level of the particulates.

Various cleaners have been known in the art to remove foreign matters present on surfaces of such substrates.

FIG. 1 is a configuration diagram of an embodiment of a conventional dry ultrasonic cleaning apparatus. The conventional dry ultrasonic cleaning apparatus is configured to include a blower 10 that injects air into glass and a film to remove inorganic foreign matters attached to surfaces of the glass and the film and an exhaust 20 that sucks and discharges the air injected through the blower 10 and the foreign matters removed by the injected air.

The blower 10 is configured so that air is injected to remove foreign matters, an air line 11 into which the air is injected is mechanically formed in a sawtooth shape to generate vibrations in the injected air and thus the air in which the vibrations are generated removes the foreign matters attached to the surfaces of the glass and the film.

However, the prior art as described above has a problem in that since the air line 11 to which the air is injected is formed in the sawtooth shape, a frequency is limited due to the occurrence of the mechanical vibrations and therefore the foreign matters are not efficiently removed, and only the high flow rate of air needs to be injected in order to increase the frequency and therefore noises occur.

In addition, there is a problem in that the foreign matters are not easily separated due to static electricity generated between the surfaces of the glass and the film and the foreign matters by the general injection of air, and after the air is injected, vortices occur until the foreign matters are separated and are sucked by the exhaust 20 and thus the foreign matters are reattached.

Meanwhile, as a prior art of the conventional dry ultrasonic cleaning apparatus, Korean Patent Publication No. 10-0754152 entitled “dry substrate cleaning apparatus” discloses a dry substrate cleaning apparatus including: a blower that supplies pressurized air; a vibration generator that includes an eddy plate generating vibrations by a friction of the pressurized air disposed at a lower portion of the blower to apply the vibrations to the pressurized air; an injector that includes a nozzle injecting the pressurized air vibrating at a lower portion of the vibration generator into a substrate and further pressurizes the pressurized air and injects the pressurized air at a lower temperature; a suction unit that includes a pair of suction ports sucking the pressurized air injected through the injector and the foreign matters disposed on both side surfaces of the injector; and ionizers that are disposed on both side surfaces of the suction unit and prevents the substrate from being charged with static electricity.

As another prior art related to the ultrasonic cleaning apparatus, there is Korean Patent Laid-Open Publication No. 2010-0078269 entitled “dry type ultrasonic cleaning apparatus for a substrate”. The prior art discloses a dry ultrasonic cleaning apparatus for a substrate including a compressed air injector that injects ultrasonic air into a substrate to separate foreign matters from the substrate and a vacuum suction unit that sucks and removes the separated foreign matters, in which the compressed air injector includes: an adsorption prevention part that includes a plurality of nozzles that inject the compressed air at a predetermined angle other than a vertical angle to the substrate and are disposed on a bottom surface of the substrate and has a suction force varying in proportion to a suction force of the vacuum suction unit; and an air curtain generator that generates an air curtain from both side surfaces of the vacuum suction unit toward the substrate.

However, the ultrasonic cleaning apparatus for removing particulates should be able to prevent damage to the substrate during the removal of the particulates, and at the same time, completely separate the foreign matters separated from the substrate. To this end, a means for effectively inducing the foreign matters separated from the substrate while appropriately adjusting the air injecting type according to the type of substrates is required, and the known ultrasonic cleaning apparatus does not disclose the means.

### RELATED ART DOCUMENT

### [Patent Document]

(Patent Document 0001) Korean Patent No. 10-0966903 (Published on Jun. 30, 2010)
(Patent Document 0002) Korean Patent No. 10-0754152 (Published on Sep. 3, 2007)
(Patent Document 0003) Korean Patent No. 10-1040706 (Published on Jun. 10, 2011)
(Patent Document 0004) Korean Patent Laid-Open Publication No. 10-2010-0062134 (Published on Jun. 10, 2010)

### SUMMARY

The present invention provides a dry type ultrasonic cleaner having a multi-suction port that can generate ultrasonic waves through a uniform pneumatic to quickly, uniformly, and reliably remove particles on a product to be cleaned through the multi-suction port without scattering.

The present invention also provides a dry type ultrasonic cleaner having a multi-suction port that can remove a wide range of particles having a size of several micrometers (μm) to several millimeters (mm) to secure product competitiveness.

The present invention also provides a dry type ultrasonic cleaner having a multi-suction port that can reliably clean a cleaning product even during transportation of a relatively large cap and the cleaning product.

The effects of the present disclosure are not limited to those mentioned above, and other effects not mentioned can be clearly understood by those skilled in the art from the following description.

In an aspect, a dry type ultrasonic cleaner having a multi-suction port includes: a cleaner housing that has a lower surface provided a plurality of ultrasonic air discharge ports and a plurality of particle suction ports, an upper surface provided with a connection pipe connected to a suction pressure generation device, and one side provided with an air injection port; a plurality of ultrasonic discharge block members that are provided in the cleaner housing and has an upper end portion communicating with the air injection port and a lower end portion provided with an ultrasonic discharge forming path communicating with the ultrasonic air discharge port; and a flow rate control means that is provided on the ultrasonic discharge forming path to control the flow rate of air passing through the ultrasonic discharge forming path so as to make a pneumatic pressure uniform.

The plurality of ultrasonic air discharge ports and the plurality of particle suction ports may be alternately formed, and are formed in a slit form along a length direction on a rear surface of the cleaner housing.

The particle suction port may include a slit-type first particle suction port of a predetermined length that is formed at a central portion on the rear surface of the cleaner housing, and a slit-type second particle suction port on one side and a slit-type second particle suction port on the other side that are formed at both edges on the rear surface of the cleaner housing, the ultrasonic air discharge port may include a slit-type first ultrasonic air discharge port formed between the first particle suction port and the second particle suction port on one side, and a slit-type second ultrasonic air discharge port formed between the first particle suction port and the second particle suction port on the other side, an upper portion of the ultrasonic air discharge port may be formed in a cross-section inverted triangle, and the first particle suction port and the second particle port may be formed to communicate with the connection pipe.

The ultrasonic air discharge port may have a slit width of 0.2 mm.

The ultrasonic discharge forming path may include: a base linear line that has a lower end portion communicating with the ultrasonic air discharge port, a first extending part that forms an upper end portion of the base linear line and communicates with the air injection port, a second extending part that is formed on the base linear line below the first extending part and is formed to have a relatively smaller cross-sectional area than that of the first extending part, a third extending part that is formed on the base linear line below the second extending part and is formed to have a relatively smaller cross-sectional area than that of the second extending part, and a fourth extending part that is formed at a lower end of the base linear line and is formed by extending to both sides from the base linear line.

The first extending part may be formed in a dome shape in which a cross-sectional shape when viewed in a longitudinal direction of the ultrasonic discharge block member extends from one side of the base linear line, the second extending part may have a circular cross-sectional shape when viewed in the longitudinal direction of the ultrasonic discharge block member, and the third extending part and the fourth extending part may have a rectangular cross-sectional shape when viewed in the longitudinal direction of the ultrasonic discharge block member.

The flow rate control means may include a rod-shape body, and a spiral groove spirally formed on an outer surface of the rod-shape body, and the flow rate control means may be provided in the second extending part.

### BRIEF DESCRIPTION OF THE DRAWINGS

FIG. 1 is a schematic diagram of an ultrasonic cleaner according to the prior art.

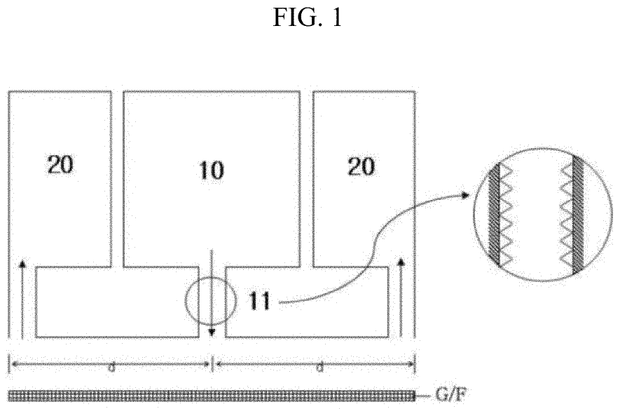

FIG. 2 is a perspective view from above of a dry type ultrasonic cleaner having a multi-suction port according to the present invention.

FIG. 3 is a perspective view of the dry type ultrasonic cleaner having a multi-suction port according to the present invention as viewed from the bottom side.

FIG. 4 is a rear view showing the dry type ultrasonic cleaner having a multi-suction port according to the present invention.

FIG. 5 is a longitudinal cross-sectional view showing the dry type ultrasonic cleaner having a multi-suction port according to the present invention.

FIG. 6 is a view showing an embodiment of a pneumatic equal generation means included in the dry type ultrasonic cleaner having a multi-suction port according to the present invention.

FIG. 7 is a conceptual diagram for describing an operation of the dry type ultrasonic cleaner having a multi-suction port according to the present invention.

FIG. 8 is a photograph of results of confirming particle removal performance through the prototype dry type ultrasonic cleaner having a multi-suction port according to the present invention, which shows experimental results for a wheat meal having a size of several micrometers to several hundreds of micrometers.

FIG. 9 is a photograph of results of confirming the particle removal performance through the prototype dry type ultrasonic cleaner having a multi-suction port according to the present invention, which shows experimental results for a solder ball having a size of 500 micrometers.

FIG. 10 is a photograph of results of confirming the particle removal performance through the prototype dry type ultrasonic cleaner having a multi-suction port according to the present invention manufactured, which shows experimental results for silicon dioxide (SiO₂) having a size of 1 micrometer.

### DETAILED DESCRIPTION OF EMBODIMENTS

Additional objects, features and advantages of the present invention may be more clearly understood from the following detailed description and the accompanying drawings.

Prior to the detailed description of the present invention, the present invention may be variously modified, and may have various embodiments, and the examples described below and illustrated in the drawings are intended to limit the present invention to specific embodiments, and it is to be understood that all changes, equivalents, and substitutes included in the spirit and scope of the present invention are included.

It is to be understood that when one element is referred to as being “connected to” or “coupled to” another element, it may be connected directly to or coupled directly to another element or be connected to or coupled to another element, having the other element intervening therebetween. On the other hand, it should be understood that when one element is referred to as being “connected directly to” or “coupled directly to” another element, it may be connected to or coupled to another element without the other element interposed therebetween.

Terms used in the present specification are used only in order to describe specific exemplary embodiments rather than limiting the present invention. Singular forms are intended to include plural forms unless the context clearly indicates otherwise. It should be further understood that terms “include” or “have” used in the present specification specify the presence of features, numerals, steps, operations, components, parts mentioned in the present specification, or combinations thereof, but do not preclude the presence or addition of one or more other features, numerals, steps, operations, components, parts, or combinations thereof.

A term “-er/or”, “unit”, “module”, “block” or the like, described in the specification means a processing unit of at least one function or operation and may be implemented by hardware or software or a combination of hardware and software.

In addition, in the description with reference to the accompanying drawings, regardless of reference numerals, the same components will be given the same reference numerals and duplicate description thereof will be omitted. When it is decided that the detailed description of the known art related to the present invention may unnecessary obscure the gist of the present invention, a detailed description therefor will be omitted.

In addition, throughout this specification, when a step is located “on” or “before” with another step, not only the case in which a step is in direct time series relationship with another step, but also the case in which like a mixing step after each step, a step is in direct time series relationship in which a time series order in two steps may be reversed include the same rights.

Hereinafter, a dry type ultrasonic cleaner having a multi-suction port according to a preferred embodiment of the present invention will be described in detail with reference to the accompanying drawings.

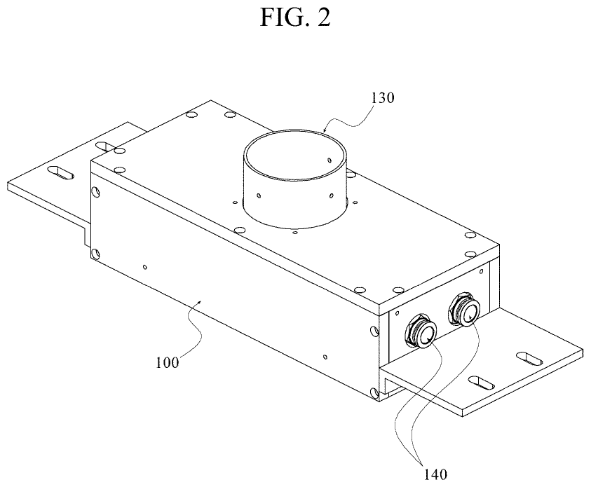

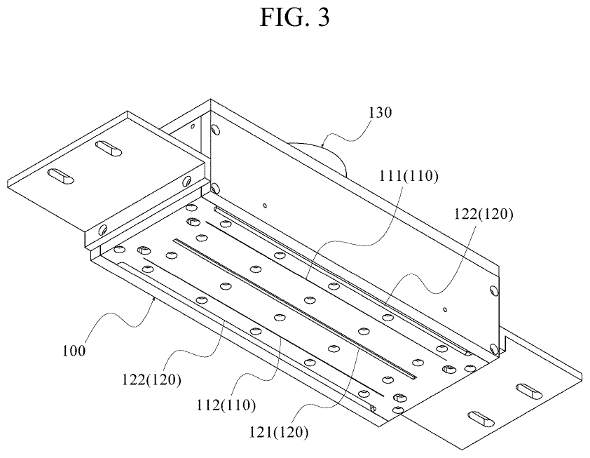

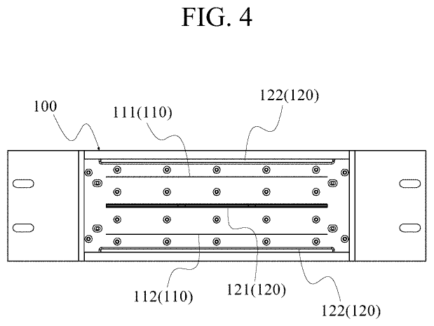

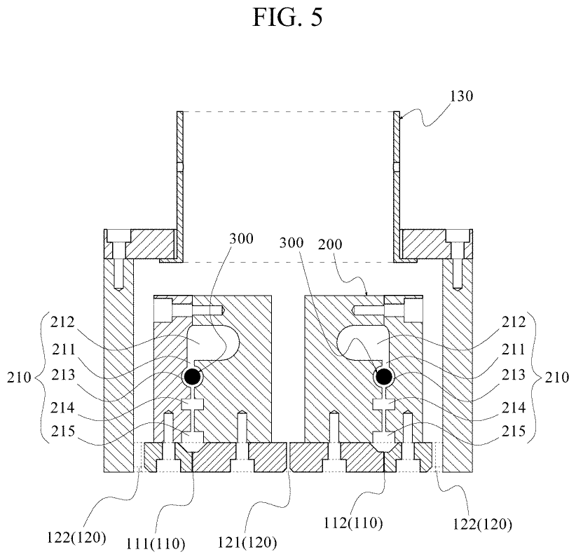

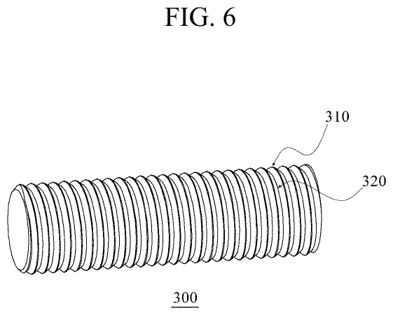

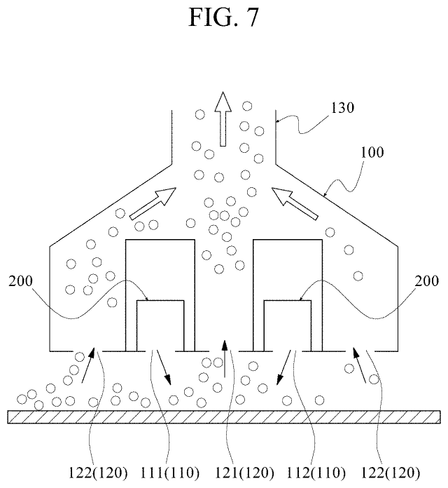

FIG. 2 is a perspective view of a dry type ultrasonic cleaner having a multi-suction port according to the present invention as viewed from the top side, FIG. 3 is a perspective view of the dry type ultrasonic cleaner having a multi-suction port according to the present invention as viewed from the bottom side, and FIG. 4 is a rear view showing the dry type ultrasonic cleaner having a multi-suction port according to the present invention. FIG. 5 is a longitudinal cross-sectional view showing the dry type ultrasonic cleaner having a multi-suction port according to the present invention, FIG. 6 is a view showing an embodiment of a pneumatic equal generation means included in the dry type ultrasonic cleaner having a multi-suction port according to the present invention, and FIG. 7 is a conceptual diagram for describing an operation of the dry type ultrasonic cleaner having a multi-suction port according to the present invention.

As shown in FIGS. 2 to 7, the dry type ultrasonic cleaner having a multi-suction port according to the present invention is configured to largely include a cleaner housing 100, an ultrasonic discharge block member 200, and a flow rate control means 300.

Specifically, as shown in FIGS. 2 to 7, the dry type ultrasonic cleaner having a multi-suction port according to the present invention is configured to include: a cleaner housing 100 that has a lower surface provided a plurality of ultrasonic air discharge ports (air discharge port) 110 and a plurality of particle suction ports 120, an upper surface provided with a connection pipe 130 connected to a suction pressure (vacuum pressure) generation device (not shown), and one side provided with an air injection port 140; a plurality of ultrasonic discharge block members 200 that are provided in the cleaner housing 100 and has an upper end portion communicating with the air injection port 140 and a lower end portion provided with an ultrasonic discharge forming path 210 communicating with the ultrasonic air discharge port 110; and a flow rate control means 300 that is provided on the ultrasonic discharge forming path 210 of the ultrasonic discharge block member 200 to control the flow rate of air passing through the ultrasonic discharge forming path 210 so as to make a pneumatic pressure uniform.

More specifically, the cleaner housing 100 is formed in a rectangular enclosure, but is not limited thereto.

The plurality of ultrasonic air discharge ports 110 and the plurality of particle suction ports 120 that are formed on the lower surface (rear surface) of the cleaner housing 100 are alternately formed, and are formed in a slit form along a length direction on the rear surface of the cleaner housing 100.

More specifically, the particle suction port 120 includes a slit-type first particle suction port 121 that is formed at a central portion in a longitudinal direction on the rear surface of the cleaner housing 100, and slit-type second particle suction ports 122 that are formed at both edges in the longitudinal direction on the rear surface of the cleaner housing 100.

These first particle suction port 121 and the second particle suction port 122 are in communication with the connection pipe 130 within the cleaner housing 100.

The ultrasonic air discharge port (air discharge port) 110 is formed to communicate with a lower end of the ultrasonic discharge forming path 210 of the air discharge block member 200 to be described in detail below.

In the example illustrated in the drawings, the ultrasonic air discharge port 110 is a slit-type first ultrasonic air discharge port 111 that is formed between the first particle suction port 121 and the second particle suction port 122 on one side, an a slit-type second ultrasonic air discharge port 112 that is formed between the first particle suction port 121 and the second particle suction port 122 on the other side.

In this case, in the present invention, the ultrasonic air discharge port 110 (111 and 112) preferably has a slit width of 0.2 mm, and is closely associated with the shape of the ultrasonic discharge forming path 210 of the air discharge block member 200 to be described below and is formed to be relatively narrow to increase air discharge power and significantly increase cleaning power, which was confirmed through experiments described below.

Subsequently, the air injection hole 140 formed on one side of the cleaner housing 100 is connected to an air injection device (not shown).

Next, the ultrasonic discharge block member 200 and the ultrasonic discharge forming furnace 210 formed therein will be described.

The present invention is characterized by having a specific type of ultrasonic discharge forming path 210.

More specifically, the ultrasonic discharge forming path 210 includes a base linear line 211 that has a lower end portion communicating with the ultrasonic air discharge port 110, a first extending part 212 that forms an upper end portion of the base linear line 211 and communicates with the air injection port 140, a second extending part 213 that is formed on the base linear line 211 below the first extending part 212 and is formed to have a relatively smaller cross-sectional area than that of the first extending part 212, a third extending part 214 that is formed on the base linear line 211 below the second extending part 213 and is formed to have a relatively smaller cross-sectional area than that of the second extending part 213, and a fourth extending part 215 that is formed at a lower end of the base linear line 211 as a discharge port and is formed by extending to both sides from the base linear line 211.

As shown in FIG. 5, the first extending part 212 has a cross-sectional shape (cross-sectional shape when viewed from a side surface, that is, cross-sectional shape in an air injection direction in the example of the drawing) formed in a dome shape on one side thereof and is thus formed in an extended form from the base linear line 211

As shown in FIG. 5, the second extending part 213 has a cross-sectional shape (cross-sectional shape when viewed from a side surface, that is, cross-sectional shape in an air injection direction in the example of the drawing) formed in a circular shape and is thus formed in an extended form from the base linear line 211.

As shown in FIG. 5, the third extending part 214 and the fourth extending part 215 have a cross-sectional shape (cross-sectional shape when viewed from a side surface, that is, cross-sectional shape in an air injection direction in the example of the drawing) formed in a rectangular shape and is thus formed in an extended form from the base linear line 211.

The ultrasonic discharge forming path 210 is formed to penetrate by a predetermined length along the longitudinal direction of the ultrasonic discharge block member 200.

In addition, the ultrasonic discharge block member 200 in which the ultrasonic discharge forming path 210 is formed is configured so that the block body is divided into two and the ultrasonic discharge forming path 210 is formed on surfaces facing each other during assembly.

Here, the upper portion of the ultrasonic air discharge port 110 of the cleaner housing 100 is preferably formed so that the upper end corresponds to the fourth extending part 215 and the middle portion is formed in a cross-section inverted triangle that converges.

In addition, in the example of FIG. 5, the case where the two ultrasonic discharge block members 200 are provided in the width direction of the cleaner housing 100 is shown, but the present invention is not limited thereto.

Next, as shown in FIG. 6, the flow rate control means 300 includes a rod-shape body 310 and a spiral groove 320 spirally formed on an outer surface of the rod-shape body 310.

Here, the rod-shape body 310 of the flow rate control means 300 is formed in a cylindrical shape.

The flow rate control means 300 is configured to be provided in the second extending part 213 in the ultrasonic discharge forming path 210 of the ultrasonic discharge block member 200.

That is, the flow rate control means 300 has a length corresponding to the longitudinal direction of the second extension portion 213 of the ultrasonic discharge forming path 210 and is provided to be inserted in the longitudinal direction of the second extending part 213, but is provided in the state in which a flow path is secured between the flow rate control means 300 and an inner wall of the second extending part 213 to enable the air flow. For example, the flow rate control means 300 may be provided to be in close contact with the wall surface of the second extending part 213 with a predetermined gap.

The flow rate control means 300 provided as described above controls air to flow out along the spiral groove 320 of the flow rate control means 300 when the air flows into the first extending part 212 of the ultrasonic discharge forming path 210 and is then discharged to the ultrasonic air flow discharge port 110 through the second extending part 213, thereby controlling the flow rate to be constant and generating the ultrasonic air flow having the uniform pneumatic pressure.

Meanwhile, the inventor(s) of the present invention manufactured the dry type ultrasonic cleaner having a multi-suction port according to the present invention as a trial product and performed an experiment on the particle removal performance.

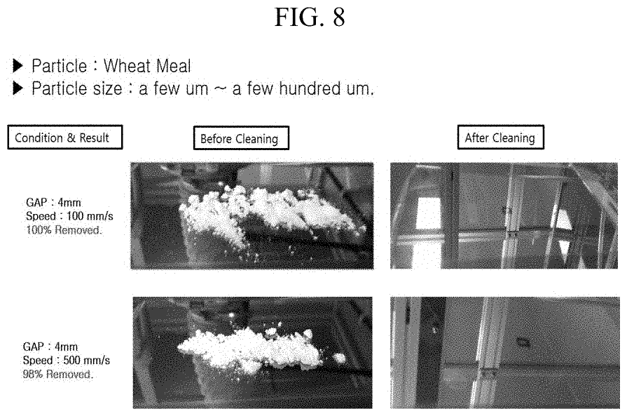

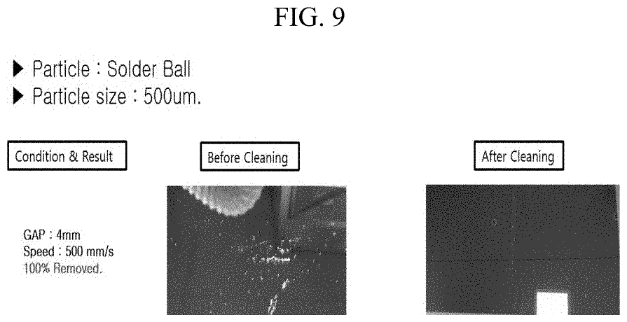

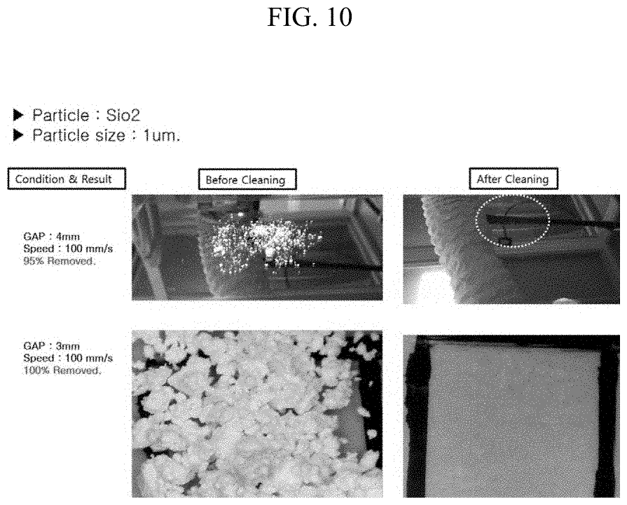

FIGS. 8 to 10 are photographs of results of confirming particle removal performance through the prototype dry type ultrasonic cleaner having a multi-suction port according to the present invention, and FIG. 8 shows experimental results for a wheat meal having a size of several micrometers to several hundreds of micrometers, FIG. 9 shows experimental results for a solder ball having a size of 500 micrometers, and FIG. 10 shows experimental results for silicon dioxide (SiO2) having a size of 1 micrometer. From the experimental results, it was confirmed that the cleaning performance is satisfied, and in particular, it was confirmed that the particles are reliably and quickly removed under the conditions that the gap between the cleaning product and the ultrasonic cleaner of the present invention was a maximum of 15 mm and the moving speed is up to 500 mm/s.

According to the dry type ultrasonic cleaner having a multi-suction port according to the present invention as described above, it is possible to reliably remove particles on the product to be cleaned by generating the ultrasonic waves through the uniform pneumatic pressure, and quickly and uniformly perform the cleaning through the multi-suction port.

In addition, the present invention can remove a wide range of particles having a size of several micrometers (μm) to several millimeters (mm) to improve the versatility and product competitiveness, and can reliably clean a cleaning product even during the transportation of the relatively large cap and the cleaning product.

Although the embodiments as described above are described by a limited drawing, those skilled in the art may apply various technical modifications and variations based on the above. For example, even though the described techniques may be performed in a different order than the described method, and/or components of the described systems, structures, devices, circuits, etc. may be combined or combined in a different manner than the described method, or replaced or substituted by other components, appropriate results can be achieved.

The embodiments and the accompanying drawings described herein are merely illustrative of some of the technical ideas included in the present invention. Therefore, since the embodiments disclosed in the present specification are not intended to limit the technical spirit of the present invention but to describe the present invention, it is obvious that the scope of the technical idea of the present invention is not limited by these embodiments. Modifications and specific embodiments that can be easily inferred by those skilled in the art within the scope of the technical spirit included in the specification and drawings of the present invention should be construed as being included in the scope of the present invention.

According to the dry type ultrasonic cleaner having a multi-suction port according to the present invention provides the following effects.

First, the present invention can reliably remove the particles on the product to be cleaned without scattering.

Second, the present invention can perform the quick and uniform cleaning through the multi-suction port.

Third, the present invention can remove a wide range of particles having a size of several micrometers (μm) to several millimeters (mm) to improve the versatility and product competitiveness.

Fourth, the present invention can reliably clean the cleaning product even during the transportation of the relatively large cap and cleaning product.

The effects of the present disclosure are not limited to those mentioned above, and other effects not mentioned can be clearly understood by those skilled in the art from the following description.

1. A dry type ultrasonic having a multi-suction port, comprising:
a cleaner housing that has a lower surface provided a plurality of ultrasonic air discharge ports and a plurality of particle suction ports, an upper surface provided with a connection pipe connected to a suction pressure generation device, and one side provided with an air injection port;
a plurality of ultrasonic discharge block members that are provided in the cleaner housing and has an upper end portion communicating with the air injection port and a lower end portion provided with an ultrasonic discharge forming path communicating with the ultrasonic air discharge port; and
a flow rate control means that is provided on the ultrasonic discharge forming path to control the flow rate of air passing through the ultrasonic discharge forming path so as to make a pneumatic pressure uniform.

2. The dry type ultrasonic having a multi-suction port of claim 1, wherein the plurality of ultrasonic air discharge ports and the plurality of particle suction ports are alternately formed, and are formed in a slit form along a length direction on a rear surface of the cleaner housing.

3. The dry type ultrasonic having a multi-suction port of claim 1, wherein the particle suction port includes a slit-type first particle suction port of a predetermined length that is formed at a central portion on the rear surface of the cleaner housing, and a slit-type second particle suction port on one side and a slit-type second particle suction port on the other side that are formed at both edges on the rear surface of the cleaner housing,
the ultrasonic air discharge port includes a slit-type first ultrasonic air discharge port formed between the first particle suction port and the second particle suction port on one side, and a slit-type second ultrasonic air discharge port formed between the first particle suction port and the second particle suction port on the other side,
an upper portion of the ultrasonic air discharge port is formed in a cross-section inverted triangle, and
the first particle suction port and the second particle port are formed to communicate with the connection pipe.

4. The dry type ultrasonic having a multi-suction port of claim 2, wherein the ultrasonic air discharge port has a slit width of 0.2 mm.

5. The dry type ultrasonic having a multi-suction port of claim 1, wherein the ultrasonic discharge forming path includes:
a base linear line that has a lower end portion communicating with the ultrasonic air discharge port;
a first extending part that forms an upper end portion of the base linear line and communicates with the air injection port;
a second extending part that is formed on the base linear line below the first extending part and is formed to have a relatively smaller cross-sectional area than that of the first extending part;
a third extending part that is formed on the base linear line below the second extending part and is formed to have a relatively smaller cross-sectional area than that of the second extending part; and
a fourth extending part that is formed at a lower end of the base linear line and is formed by extending to both sides from the base linear line.

6. The dry type ultrasonic having a multi-suction port of claim 5, wherein the first extending part is formed in a dome shape in which a cross-sectional shape when viewed in a longitudinal direction of the ultrasonic discharge block member extends from one side of the base linear line,
the second extending part has a circular cross-sectional shape when viewed in the longitudinal direction of the ultrasonic discharge block member, and
the third extending part and the fourth extending part have a rectangular cross-sectional shape when viewed in the longitudinal direction of the ultrasonic discharge block member.

7. The dry type ultrasonic having a multi-suction port of claim 5, wherein the flow rate control means includes a rod-shape body, and a spiral groove spirally formed on an outer surface of the rod-shape body, and
the flow rate control means is provided in the second extending part.
